(19) United States
(12) Patent Application Publication
(10) Pub. No.: US 2026/0196445 A1
(43) Pub. Date: Jul. 9, 2026

(54) SUBSTRATE PROCESSING APPARATUS WITH RADICAL CONTROLLER

(71) Applicant: SAMSUNG ELECTRONICS CO., LTD., Suwon-si (KR)

(72) Inventors: Taeseung YU, Suwon-si (KR); Hanbyul KANG, Suwon-si (KR); Jaeho KIM, Suwon-si (KR); Joonhyong CHO, Suwon-si (KR)

(73) Assignee: SAMSUNG ELECTRONICS CO., LTD., Suwon-si (KR)

(21) Appl. No.: 19/269,499

(22) Filed: Jul. 15, 2025

(30) Foreign Application Priority Data
Jan. 7, 2025 (KR) 10-2025-0002337

(51) Int. Cl. H01J 37/32

(52) U.S. Cl. CPC H01J 37/32623; H01J 37/3244; H01J 2237/334; H01J 2237/335

(57) ABSTRACT

A substrate processing apparatus includes a chamber; a supporting member inside the chamber to support a substrate; and a shower head connected to the chamber, in which the shower head comprises a plurality of regions, and in which at least two regions of the plurality of regions of the shower head have different surface recombination coefficients for radicals.

### CROSS-REFERENCE TO RELATED APPLICATION

This application claims priority to and the benefit of Korean Patent Application No. 10-2025-0002337 filed at the Korean Intellectual Property Office on Jan. 7, 2025, the entire contents of which are incorporated herein by reference.

### BACKGROUND

### (a) Field

The present disclosure relates to a substrate processing apparatus.

### (b) Description of the Related Art

In order to manufacture a semiconductor device, a desired pattern is formed on a substrate through various processes, such as photolithography, etching, ashing, ion implantation, thin-film deposition, and cleaning processes. Among them, the etching process, which serves to remove a selected heating region from a layer formed on a substrate, includes a wet etching process and a dry etching process.

Among them, for dry etching, an etching device is employed using plasma. In general, an electromagnetic field is formed in an inner space of a chamber to form the plasma, and the electromagnetic field excites process gas provided in the chamber to be in a plasma state.

The plasma refers to the state of gas ionized while including ions, electrons, and radicals. The plasma is generated due to a significantly high temperature, a strong electric field, or radio frequency (RF) electromagnetic fields. The manufacturing process of a semiconductor device may include an etching process using the plasma. However, in a substrate processing apparatus that uses plasma, radicals can be used to treat the substrate. Radicals have a strong tendency to recombine. Accordingly, the longer the path that the radicals move, the lower the density of the radicals, which causes a deviation in the density of radicals supplied to the substrate. Usually, the center area of the substrate has a shorter path of radicals than the edge area of the substrate. As such, the density of the radicals is higher as the center of the substrate.

### SUMMARY

Embodiments attempt to provide a substrate processing apparatus capable of controlling the distribution of radicals included in plasma.

However, the embodiments of the present disclosure are not limited to thereto, and may be variously extended within the scope of the technical ideas included herein.

According to an aspect of the disclosure, a substrate processing apparatus, includes: a chamber; a supporting member inside the chamber to support a substrate; and a shower head connected to the chamber, in which the shower head comprises a plurality of regions, and in which at least two regions of the plurality of regions of the shower head have different surface recombination coefficients for radicals.

According to an aspect of the disclosure, a substrate processing apparatus, includes: a chamber; a supporting member inside the chamber to support a substrate; a plasma source configured to supply plasma into the interior of the chamber; and a shower head connected to the chamber and having a plurality of distribution holes, in which the shower head comprises a plurality of regions, and in which each region of the plurality of regions has different surface recombination coefficients for radicals on inner walls of the plurality of distribution holes.

According to an aspect of the disclosure, a substrate processing apparatus includes a chamber; a supporting member inside the chamber to support a substrate; a shower head dividing an interior of the chamber into a process space and a gas distribution space, the shower head having a plurality of distribution holes; and a plasma source configured to supply plasma to the gas distribution space, in which the shower head has a plurality of regions, and in which each region of the plurality of regions of the shower head have different surface recombination coefficients for radicals on inner walls of the plurality of distribution holes.

According to the embodiments, a substrate processing apparatus that controls the distribution of radicals included in plasma may be provided.

### BRIEF DESCRIPTION OF THE DRAWINGS

FIG. 1 illustrates a substrate processing apparatus according to one or more embodiments.

FIG. 2 illustrates a shower head of FIG. 1 according to one or more embodiments.

FIG. 3 illustrates a shower head according to one or more embodiments.

FIG. 4 illustrates a shower head according to one or more embodiments.

FIG. 5 illustrates a portion of a shower head according to one or more embodiments.

FIG. 6 illustrates a shower head according to one or more embodiments.

FIG. 7 illustrates a shower head according to one or more embodiments.

FIG. 8 illustrates a shower head according to one or more embodiments.

FIG. 9 illustrates a shower head according to one or more embodiments.

FIG. 10 illustrates a shower head according to one or more embodiments.

FIG. 11 illustrates a shower head according to one or more embodiments.

FIG. 12 illustrates a substrate processing apparatus according to one or more embodiments.

FIG. 13 illustrates a substrate processing apparatus according to one or more embodiments.

### DETAILED DESCRIPTION OF THE EMBODIMENTS

The present disclosure will be described in detail hereinafter with reference to the accompanying drawings, in which embodiments of the present disclosure are shown. As those skilled in the art would realize, the described embodiments may be modified in various different ways, all without departing from the spirit or scope of the present disclosure.

The drawings and description are to be regarded as illustrative in nature and not restrictive, and like reference numerals designate like elements throughout the specification.

Further, since sizes and thicknesses of components shown in the accompanying drawings may be arbitrarily given to facilitate understanding and ease of description, the disclosure is not limited to the illustrated sizes and thicknesses. In the drawings, the thicknesses of layers and regions are exaggerated for clarity. In the drawings, to facilitate understanding and ease of description, the thicknesses of some layers and regions may be exaggerated.

It should be understood that when an element such as a layer, film, region, or substrate is referred to as being “on” another element, it may be directly on the other element or intervening elements may also be present. In contrast, when an element is referred to as being “directly on” another element, there are no intervening elements present. Further, when an element is referred to as being “on” or “above” a reference element, it may be positioned above or below the reference element, and it may not necessarily be referred to as being positioned “on” or “above” it in a direction opposite to gravity.

In addition, unless explicitly stated to the contrary, the word “comprise,” and variations such as “comprises” and “comprising,” should be understood to imply the inclusion of stated elements but not the exclusion of any other elements.

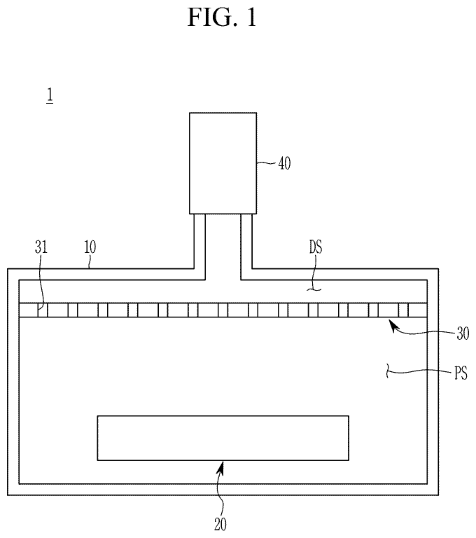

FIG. 1 illustrates a substrate processing apparatus 1 according to one or more embodiments.

Referring to FIG. 1, the substrate processing apparatus 1 according to one or more embodiments may include a chamber 10, a supporting member 20, a shower head 30, and a plasma source 40.

The substrate processing apparatus 1 processes a substrate. The substrate processing apparatus 1 may process the substrate using plasma. For example, the substrate processing apparatus 1 may perform an etching process, a cleaning process, or the like using excited plasma. The plasma excited in the substrate processing apparatus 1 may contain radicals. The substrate processing apparatus 1 may process the substrate using radicals. The substrate may be a wafer or the like for manufacturing semiconductor devices.

The chamber 10 provides a process space PS inside of which a substrate processing process is performed. The chamber 10 may be provided in a sealed configuration, with the internal process space PS. The chamber 10 may be provided with a metallic material. For example, the chamber 10 may be provided with a material such as aluminum. The chamber 10 may be grounded.

The supporting member 20 is disposed inside the chamber 10. The supporting member 20 may be disposed at the lower portion of the process space PS. The supporting member 20 supports the substrate. The supporting member 20 may fix the substrate using electrostatic force. In one or more examples, the supporting member 20 may be located on the bottom of the chamber 10. In one or more examples, the supporting member 20 may be mounted on a mounting table.

The shower head 30 may include an upper surface facing upward and a lower surface facing downward. The shower head 30 may be connected to the chamber 10. The interior of the chamber 10 may be divided into the process space PS and a gas distribution space DS by the shower head 30.

The shower head 30 is disposed to be spaced apart from the supporting member 20 in the vertical direction so that the process space PS may be positioned under the shower head 30. The shower head 30 may allow the gas supplied into the interior of the chamber 10 to be distributed and supplied to the process space PS positioned on the supporting member 20.

A plurality of distribution holes 31 may be positioned in the shower head 30. For example, the plurality of distribution holes 31 may be positioned on a plurality of concentric circles. Depending on the region, the size of the distribution hole 31 may vary. The distribution hole 31 may be provided as a hole structure facing in the vertical direction. The top of the distribution hole 31 may be connected to the upper surface of the shower head 30. The bottom of the distribution hole 31 may be connected to the lower surface of the shower head 30. In one or more examples, the distribution holes 31 in the shower head 30 may each be the same size. In one or more examples, the size of the distribution holes 31 nin the shower head 30 may vary such that at least two distribution holes have a different size. In one or more examples, the distribution holes 31 may be equally spaced apart in the shower head 30. In one or more examples, the distribution of the distribution holes 31 may vary, where a concentration of the distribution holes increases or decrease based on a location on the shower head 31. For example, the concentration of the distribution holes 31 may be greater in a region closer to the center of the shower head 30 or a region closer to an edge of the shower head 30.

The gas distribution space DS may be positioned above the upper surface of the shower head 30. The upper surface of the shower head 30 is positioned apart from the lower surface of the upper wall of the chamber 10 so that the gas distribution space DS may be formed between the upper surface of the shower head 30 and the lower surface of the upper wall of the chamber 10. The gas distribution space DS may be connected to the distribution hole 31. Accordingly, the gas supplied to the gas distribution space DS may be supplied to the process space PS through the distribution holes 31.

The plasma source 40 may allow plasma to be supplied to the interior of the chamber 10. The plasma source 40 may allow plasma to be supplied to the gas distribution space DS. The plasma source 40 may supply gas excited in a plasma state to the interior of the chamber 10. For example, the plasma source 40 may include a structure for exciting gas into a plasma state. Accordingly, the plasma source 40 may excite gas into a plasma state and then discharge it to the outside. The plasma source 40 may be connected to the chamber 10. The plasma source 40 may be connected to the upper portion of the chamber 10. For example, the plasma source 40 may be connected to the central region of the upper wall of the chamber 10. Gas in a plasma state supplied by the plasma source 40 may flow into the gas distribution space DS.

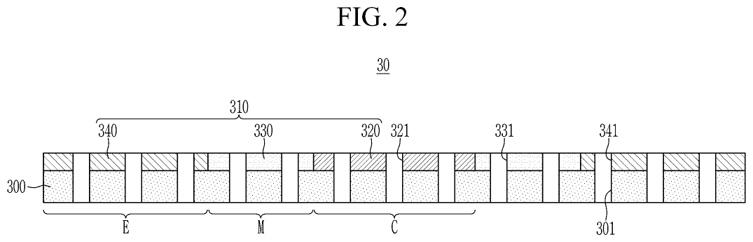

FIG. 2 illustrates the shower head 30 of FIG. 1.

Referring to FIG. 2, the shower head 30 may include a base 300 and a radical controller 310.

The shower head 30 may be provided with different surface recombination coefficients for radicals, depending on the region. The shower head 30 may provide different surface recombination coefficients for radicals on the inner walls of the plurality of distribution holes 31 for each region. The surface recombination coefficient for radicals is a coefficient that represents the rate at which radicals recombine after reaching the surface of an object. Hereinafter, the surface recombination coefficient for radicals is referred to as the surface recombination coefficient. In one or more examples, a recombination coefficient or a surface recombination coefficient may quantify a rate at which ions and electrons recombine, forming neutral atoms or molecules. The types of recombination may include ion-ion recombination (e.g., direct recombination of positive and negative ions), radiative recombination (e.g., electrons and ions recombining and releasing energy in the form of photons), or non-radiative recombination (e.g., occurring through intermediate energy levels or defects in the material, leading to heat dissipation).

The base 300 may provide a frame for the shower head 30. The base 300 may be provided as a plate structure having a predetermined area. The lower surface of the base 300 may be the lower surface of the shower head 30. A plurality of base-side holes 301 may be positioned on the base 300. For example, the plurality of base-side holes 301 may be positioned on a plurality of concentric circles. Depending on the region, the size of the base-side hole 301 may vary. The base 300 may be provided with a material such as silicone.

The base 300 may include a center region C, a middle region M, and an edge region E. The center region C may be positioned at the center of the base 300 and have a predetermined area. The center region C may be a circle having a predetermined length in a radial direction. The middle region M may be positioned on the outer circumference of the center region C and have a predetermined area. The middle region M may be a ring shape having a predetermined width in the radial direction. The edge region E may be positioned on the outer circumference of the middle region M and have a predetermined area. The edge region E may be a ring shape having a predetermined width in the radial direction. Below, a case where there is one middle region M between the center region C and the edge region E is described as an example. However, a plurality of middle regions M may be positioned between the center region C and the edge region E. In one or more examples, the middle region M may be omitted, and the center region C and the edge region E may be positioned to be in contact with each other. In one or more examples, the predetermined areas of the center region C, the middle region M, and the edge region E may be the same size. In one or more examples, the predetermined areas of the center region C, the middle region M, and the edge region E may vary from one another.

The radical controller 310 may be disposed on the base 300. A plurality of controller-side holes 321, 331, and 341 may be positioned in the radical controller 310. The controller-side holes 321, 331, and 341 may be aligned vertically with the base-side holes 301. The radical controller 310 may be a structure configured to control the rate at which radicals are provided to a predetermined area or space.

The radical controller 310 may be provided with a different surface recombination coefficient from that of the base 300. The radical controller 310 may be provided with a material having a different surface recombination coefficient from that of the base 300. The radical controller 310 may provide different surface recombination coefficients for each region of the shower head 30. The radical controller 310 has a plate structure and may be detachably provided on the base 300. The radical controller 310 may include a center radical controller 320, a middle radical controller 330, and an edge radical controller 340.

The center radical controller 320 may be disposed on the center region C of the base 300. The upper surface of the center radical controller 320 may be the upper surface of the center region of the shower head 30. The center radical controller 320 may have a shape corresponding to the center region C of the base 300. For example, the center radical controller 320 may be a circular plate structure having a predetermined area and a predetermined thickness. The center radical controller 320 has a plate structure and may be provided detachably on the base 300. A plurality of center controller-side holes 321 may be positioned in the center radical controller 320. When the center radical controller 320 is disposed on the base 300, the center controller-side hole 321 may be aligned vertically with the base-side hole 301. Accordingly, the center controller-side hole 321 may form the upper portion of the distribution hole 31, and the base-side hole 301 may form the lower portion of the distribution hole 31.

The center radical controller 320 may be provided with a different surface recombination coefficient from that of the base 300. The center radical controller 320 may be provided with a material having a different surface recombination coefficient from that of the base 300.

The middle radical controller 330 may be disposed on the middle region M of the base 300. The middle radical controller 330 may be disposed on the outer circumference of the center radical controller 320. The upper surface of the middle radical controller 330 may be the upper surface of the middle region of the shower head 30. The middle radical controller 330 may have a shape corresponding to the middle region M of the base 300. For example, the middle radical controller 330 may be a ring-shaped plate structure having a predetermined thickness with a predetermined width in the radial direction. The middle radical controller 330 may have a plate structure and may be detachably provided on the base 300. A plurality of middle controller-side holes 331 may be positioned in the middle radical controller 330. When the middle radical controller 330 is disposed on the base 300, the middle controller-side hole 331 may be aligned vertically with the base-side hole 301. Accordingly, the middle controller-side hole 331 may form the upper portion of the distribution hole 31, and the base-side hole 301 may form the lower portion of the distribution hole 31.

The middle radical controller 330 may be provided with a different surface recombination coefficient from that of the base 300. The middle radical controller 330 may be provided with a material having a different surface recombination coefficient from that of the base 300. If the middle region M of the base 300 is omitted, the middle radical controller 330 may be omitted.

The edge radical controller 340 may be disposed on the edge region E of the base 300. The edge radical controller 340 may be disposed on the outer circumference of the middle radical controller 330. The upper surface of the edge radical controller 340 may be the upper surface of the edge region of the shower head 30. The edge radical controller 340 may have a shape corresponding to the edge region E of the base 300. For example, the edge radical controller 340 may be a ring-shaped plate structure with a predetermined thickness and a predetermined width in the radial direction. The edge radical controller 340 may have a plate structure and may be detachably provided on the base 300. A plurality of edge controller-side holes 341 may be positioned in the edge radical controller 340. When the edge radical controller 340 is disposed on the base 300, the edge controller-side hole 341 may be aligned vertically with the base-side hole 301. Accordingly, the edge controller-side hole 341 may form the upper portion of the distribution hole 31, and the base-side hole 301 may form the lower portion of the distribution hole 31.

The edge radical controller 340 may be provided with a different surface recombination coefficient from that of the base 300. The edge radical controller 340 may be provided with a material having a different surface recombination coefficient from that of the base 300.

The center radical controller 320, the middle radical controller 330, and the edge radical controller 340 may be provided with different surface recombination coefficients. The center radical controller 320, the middle radical controller 330, and the edge radical controller 340 may be provided with materials having different surface recombination coefficients.

Accordingly, the shower head 30 may provide surface recombination coefficients of some of the plurality of distribution holes 31 that are different from those of the remaining surface recombination coefficients. The upper portions of the plurality of distribution holes 31 may be provided with different surface recombination coefficients, depending on the region of the shower head 30. In one or more examples, the upper surface of the shower head 30 may be provided with different surface recombination coefficients, depending on the region. Accordingly, the substrate processing apparatus 1 according to one or more embodiments may control the density distribution of radicals in the process space PS through differences in surface recombination coefficients, depending on the region of the shower head 30.

For example, the center radical controller 320 may be provided with a material having a higher surface recombination coefficient than the middle radical controller 330 and the edge radical controller 340. The middle radical controller 330 may be provided with a material having a higher surface recombination coefficient than the edge radical controller 340. For example, the center radical controller 320 may be provided with a metal material such as aluminum, stainless steel, or any other suitable material known to one of ordinary skill in the art.. The middle radical controller 330 may be provided with a ceramic material such as Al₂O₃ (alumina), Al₂O₃ (sapphire), AlN, Y₂O₃, YOF, SiC, ZiO₂, zirconia, or any other suitable material known to one of ordinary skill in the art. Furthermore, the edge radical controller 340 may be provided with a quartz material such as quartz, silica glass, or any other suitable material known to one of ordinary skill in the art.

Accordingly, the surface recombination coefficient of the inner wall of the distribution holes 31 positioned in the center region of the shower head 30 may be greater than the surface recombination coefficient of the inner wall of the distribution holes 31 positioned in the middle region and the edge region E of the shower head 30. The surface recombination coefficient of the inner wall of the distribution holes 31 positioned in the middle region of the shower head 30 may be greater than the surface recombination coefficient of the inner wall of the distribution holes 31 positioned in the edge region of the shower head 30.

In one or more examples, the surface recombination coefficient of the upper surface of the center region of the shower head 30 may be greater than the surface recombination coefficients of the upper surfaces of the middle region and the edge region E of the shower head 30. The surface recombination coefficient of the upper surface of the middle region of the shower head 30 may be greater than the surface recombination coefficient of the upper surface of the edge region of the shower head 30.

Radicals may have unpaired electrons and are therefore, may be highly reactive. Accordingly, radicals react with each other and recombine during the process of being supplied to the supporting member 20 on which the substrate is positioned. Such recombination of radicals may cause deviations in the radical distribution in the process space PS. For example, the degree of recombination of radicals may increase, depending on the path along which the radicals flow. Accordingly, the radical density distribution in the process space PS may decrease from the center region of the supporting member 20 to the edge region.

In response to these disadvantages, the substrate processing apparatus 1 according to one or more embodiments may advantageously improve the uniformity of the density distribution of radicals in the process space PS. The radicals may contact the shower head 30 in the process of moving from the gas distribution space DS to the process space PS, and accordingly, active recombination may occur on the contacting surfaces of the shower head 30. The length of the moving path of the radicals may increase from the center region to the edge region of the shower head 30. According to one or more embodiments, the substrate processing apparatus 1 provides different surface recombination coefficients on the inner wall of the distribution hole 31 and the upper surface of the shower head 30, depending on the region of the shower head 30. The shower head 30 of the substrate processing apparatus 1 according to one or more embodiments may provide a surface recombination coefficient that is larger in a region where the moving path of radicals is short than in a region where the moving path of radicals is long. Accordingly, the imbalance in the distribution of radicals along the length of their moving path may be offset by the recombination of radicals.

In one or more examples, the center radical controller 320 may be provided with a material having a lower surface recombination coefficient than the middle radical controller 330 and the edge radical controller 340. The middle radical controller 330 may be provided with a material having a lower surface recombination coefficient than the edge radical controller 340. For example, the center radical controller 320 may be provided with a quartz material such as quartz, silica glass, or the like, the middle radical controller 330 may be provided with a ceramic material such as Al₂O₃ (alumina), Al₂O₃ (sapphire), AlN, Y₂O₃, YOF, SiC, ZiO₂, zirconia, or the like, and the edge radical controller 340 may be provided with a metal material such as aluminum, stainless steel, or the like. Accordingly, the surface recombination coefficient of the inner wall of the distribution holes 31 positioned in the center region C of the shower head 30 may be less than the surface recombination coefficient of the inner wall of the distribution holes 31 positioned in the middle region and the edge region E of the shower head 30. The surface recombination coefficient of the inner wall of the distribution holes 31 positioned in the middle region of the shower head 30 may be less than the surface recombination coefficient of the inner wall of the distribution holes 31 positioned in the edge region of the shower head 30.

In one or more examples, the surface recombination coefficient of the upper surface of the center region C of the shower head 30 may be less than the surface recombination coefficients of the upper surfaces of the middle region and the edge region E of the shower head 30. The surface recombination coefficient of the upper surface of the middle region of the shower head 30 may be less than the surface recombination coefficient of the upper surface of the edge region of the shower head 30.

In the substrate processing apparatus 1, an imbalance occurs in the density distribution of radicals in the process space PS, depending on the design of the path along which the radicals move so that the density of radicals may be higher in the space on the edge region of the supporting member 20 than in the space on the center region of the supporting member 20. In response to this, the shower head 30 of the substrate processing apparatus 1, according to one or more embodiments, provides a surface recombination coefficient that is less in a region that supplies radicals onto the center region of the supporting member 20 than in a region that supplies radicals onto the edge region of the supporting member 20, thereby improving the uniformity of distribution of radicals.

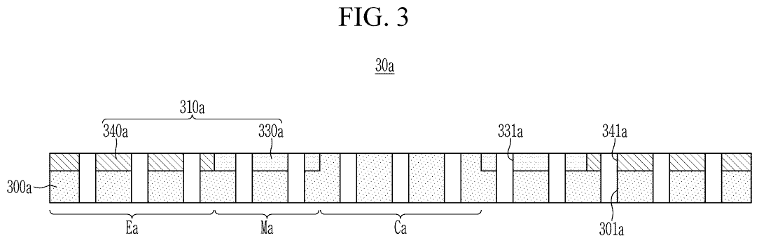

FIG. 3 illustrates a shower head 30a according to one or more embodiments.

Referring to FIG. 3, the shower head 30a according to one or more embodiments may include a base 300a and a radical controller 310a.

A plurality of base-side holes 301a may be positioned in the base 300a. The base 300a may include a center region Ca, a middle region Ma, and an edge region Ea. The upper surface of the center region Ca of the base 300a may be the upper surface of the shower head 30a. The base-side hole 301a of the center region Ca of the base 300a may be a distribution hole of the shower head 30a. The base 300a may have different thicknesses, depending on the region. For example, the base 300a may have the center region Ca which is thicker than the middle region Ma and the edge region Ea. Furthermore, similar to the description in FIG. 2, the middle region Ma may be omitted. In one or more examples, the structure of the base 300a is the same as or similar to the base 300 of FIG. 2, so repeated description is omitted.

The radical controller 310a may be disposed on at least a portion of the base 300a. The radical controller 310a may be provided with a different surface recombination coefficient from that of the base 300a.

The radical controller 310a may include a middle radical controller 330a and an edge radical controller 340a.

The middle radical controller 330a may be disposed on the middle region Ma of the base 300a. The middle radical controller 330a may be disposed on the outer circumference of the center region Ca of the base 300a. The upper surface of the middle radical controller 330a may be the upper surface of the middle region of the shower head 30a.

The middle radical controller 330a may be provided with a different surface recombination coefficient from that of the base 300a. The middle radical controller 330a may be provided with a material having a different surface recombination coefficient from that of the base 300a. If the middle region Ma of the base 300a is omitted, the middle radical controller 330a may be omitted.

The edge radical controller 340a may be disposed on the edge region Ea of the base 300a. The edge radical controller 340a may be disposed on the outer circumference of the middle radical controller 330a. The upper surface of the edge radical controller 340a may be the upper surface of the edge region of the shower head 30a.

The edge radical controller 340a may be provided with a different surface recombination coefficient from that of the base 300a. The edge radical controller 340a may be provided with a material having a different surface recombination coefficient from that of the base 300a. The edge radical controller 340a may be provided with a surface recombination coefficient different from that of the middle radical controller 330a. The edge radical controller 340a may be provided with a material having a different surface recombination coefficient from that of the middle radical controller 330a. The edge radical controller 340a may be provided with a material having a higher surface recombination coefficient than the middle radical controller 330a. In one or more examples, the edge radical controller 340a may be provided with a material having a lower surface recombination coefficient than the middle radical controller 330a.

The structures of the middle radical controller 330a and the edge radical controller 340a are the same as or similar to those described above in FIG. 2, so repeated description is omitted.

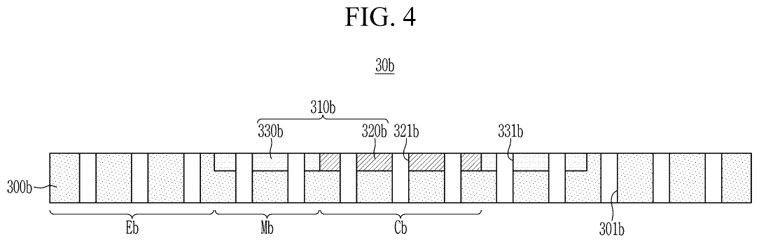

FIG. 4 illustrates a shower head 30b according to one or more embodiments.

Referring to FIG. 4, the shower head 30b according to one or more embodiments may include a base 300b and a radical controller 310b.

A plurality of base-side holes 301b may be positioned in the base 300b. The base 300b may include a center region Cb, a middle region Mb, and an edge region Eb. The upper surface of the edge region Eb of the base 300b may be the upper surface of the shower head 30b. The base-side hole 301b of the edge region Eb of the base 300b may be a distribution hole of the shower head 30b. The base 300b may have different thicknesses, depending on the region. For example, the edge region Eb may be thicker than the center region Cb and the middle region Mb. Furthermore, similar to those described above in FIG. 2, the middle region Mb may be omitted. The structure of the base 300b is the same as or similar to the base 300 of FIG. 2, so repeated description is omitted.

The radical controller 310b may be disposed on at least a portion of the base 300b. The radical controller 310b may be provided with a different surface recombination coefficient from that of the base 300b.

The radical controller 310b may include a center radical controller 320b and a middle radical controller 330b.

The center radical controller 320b may be disposed on the center region Cb of the base 300b. The upper surface of the center radical controller 320b may be the upper surface of the center region of the shower head 30b.

The center radical controller 320b may be provided with a different surface recombination coefficient from that of the base 300b. The center radical controller 320b may be provided with a material having a different surface recombination coefficient from that of the base 300b.

The middle radical controller 330b may be disposed on the middle region Mb of the base 300b. The middle radical controller 330b may be disposed on the outer circumference of the center radical controller 320b. The upper surface of the middle radical controller 330b may be the upper surface of the middle region of the shower head 30b.

The middle radical controller 330b may be provided with a surface recombination coefficient from that of the base 300b. The middle radical controller 330b may be provided with a material having a different surface recombination coefficient from that of the base 300b. The middle radical controller 330b may be provided with a different surface recombination coefficient from that of the center radical controller 320b. The middle radical controller 330b may be provided with a material having a different surface recombination coefficient from that of the center radical controller 320b. The middle radical controller 330b may be provided with a material having a higher surface recombination coefficient than the center radical controller 320b. In one or more examples, the middle radical controller 330b may be provided with a material having a lower surface recombination coefficient than the center radical controller 320b. If the middle region Mb of the base 300b is omitted, the middle radical controller 330b may be omitted.

The structures of the center radical controller 320b and the middle radical controller 330b are the same as or similar to those described above in FIG. 2, so repeated description is omitted.

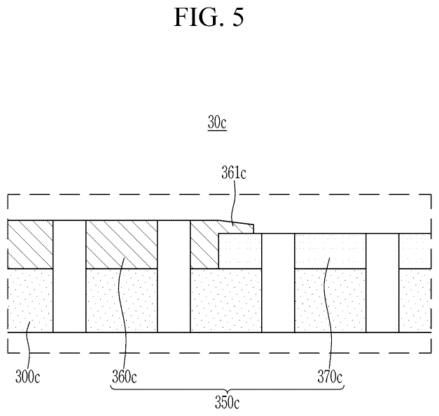

FIG. 5 illustrates a portion of a shower head 30c according to one or more embodiments.

Referring to FIG. 5, the shower head 30c according to one or more embodiments may include a base 300c and a radical controller 350c.

The base 300c is the same as or similar to the base 300 described in FIG. 2, or the base 300a described in FIG. 3, or the base 300b described in FIG. 4, so repeated descriptions are omitted.

The radical controller 350c may include a first radical controller 360c and a second radical controller 370c. The first radical controller 360c and the second radical controller 370c may be provided in contact with each other. The first radical controller 360c may include a cover portion 361c protruding toward the second radical controller 370c at an upper portion facing the second radical controller 370c. The cover portion 361c may be provided to contact the upper surface of the second radical controller 370c. The cover portion 361c may block plasma from flowing between the first radical controller 360c and the second radical controller 370c.

One of the center radical controller 320, the middle radical controller 330, and the edge radical controller 340 of FIG. 2 may be the first radical controller 360c, and one of the others may be the second radical controller 370c. In one or more examples, one of the middle radical controller 330a and the edge radical controller 340a of FIG. 3 may be the first radical controller 360c, and the other may be the second radical controller 370c. In one or more examples, one of the center radical controller 320b and the middle radical controller 330b of FIG. 4 may be the first radical controller 360c, and the other may be the second radical controller 370c.

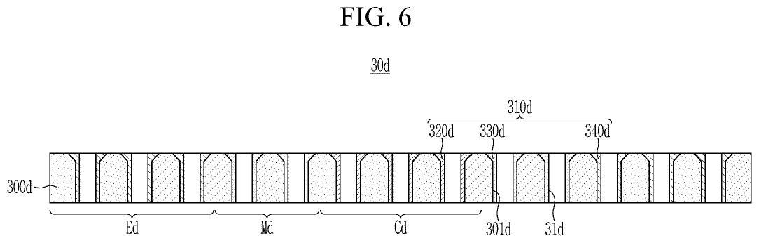

FIG. 6 illustrates a shower head 30d according to one or more embodiments.

Referring to FIG. 6, the shower head 30d according to one or more embodiments may include a base 300d and a radical controller 310d.

The shower head 30d may provide different surface recombination coefficients for each region on the inner walls of a plurality of distribution holes 31d.

The base 300d may provide a frame for the shower head 30d. The base 300d may be provided as a plate structure having a predetermined area. The lower surface of the base 300d may be the lower surface of the shower head 30d. The upper surface of the base 300d may be the upper surface of the shower head 30d.

A plurality of base-side holes 301d may be positioned in the base 300d. For example, the plurality of base-side holes 301d may be positioned on a plurality of concentric circles. Depending on the region, the size of the base-side hole 301d may vary. The upper portion of the base-side hole 301d may increase in area as it goes upward. The base 300d may be provided with a material such as silicone.

The base 300d may include a center region Cd, a middle region Md, and an edge region Ed. The center region Cd may be positioned at the center of the base 300d and have a predetermined area. The center region Cd may be a circle having a predetermined length in a radial direction. The middle region Md may be positioned on the outer circumference of the center region Cd and have a predetermined area. The middle region Md may be ring-shaped with a predetermined width in the radial direction. The edge region Ed may be positioned on the outer circumference of the middle region Md and have a predetermined area. The edge region Ed may be ring-shaped and have a predetermined width in the radial direction. Below, a case where there is one middle region Md between the center region Cd and the edge region Ed is described as an example. However, a plurality of middle regions Md may be positioned between the center region Cd and the edge region Ed. In one or more examples, the middle region Md may be omitted, and the center region Cd and the edge region Ed may be positioned to be in contact with each other.

The radical controller 310d may be inserted and disposed in the base-side hole 301d of the base 300d. The radical controller 310d may have a pipe structure with a predetermined length, and may be inserted and disposed in the base-side hole 301d. Accordingly, the inner surface of the radical controller 310d may be the distribution hole 31d of the shower head 30d.

The length of the radical controller 310d may correspond to the thickness of the base 300d in the vertical direction. The outer surface of the radical controller 310d may correspond to the shape of the base-side hole 301d. For example, the outer surface of the upper portion of the radical controller 310d may be inclined toward the outside as it goes upward.

The radical controller 310d may be provided with a different surface recombination coefficient from that of the base 300d. The radical controller 310d may provide different surface recombination coefficients for each region of the shower head 30d. The radical controller 310d may include a center radical controller 320d, a middle radical controller 330d, and an edge radical controller 340d.

The center radical controller 320d may be inserted and disposed in the base-side hole 301d positioned in the center region Cd of the base 300d. A plurality of center radical controllers 320d are provided corresponding to the base-side holes 301d positioned in the center region Cd of the base 300d so that the center radical controllers 320d may each be disposed in the base-side holes 301d positioned in the center region Cd of the base 300d. The inner surface of the center radical controller 320d may be the distribution hole 31d in the center region of the shower head 30d.

The top of the center radical controller 320d forms a coplanar surface with the upper surface of the base 300d, which may be a part of the upper surface of the shower head 30d. The bottom of the center radical controller 320d forms a coplanar surface with the lower surface of the base 300d, which may be a part of the lower surface of the shower head 30d.

The center radical controller 320d may be provided with a different surface recombination coefficient from that of the base 300d. The center radical controller 320d may be provided with a material having a different surface recombination coefficient from that of the base 300d.

The middle radical controller 330d may be inserted and disposed in the base-side hole 301d positioned in the middle region Md of the base 300d. A plurality of middle radical controllers 330d are provided corresponding to the base-side holes 301d positioned in the center region Cd of the base 300d so that the middle radical controllers 330d may each be disposed in the base-side holes 301d positioned in the middle region Md of the base 300d. The inner surface of the middle radical controller 330d may be the distribution hole 31d in the center region of the shower head 30d.

The top of the middle radical controller 330d forms a coplanar surface with the upper surface of the base 300d, which may be a part of the upper surface of the shower head 30d. The bottom of the middle radical controller 330d forms a coplanar surface with the lower surface of the base 300d, which may be a part of the lower surface of the shower head 30d.

The middle radical controller 330d may be provided with a different surface recombination coefficient from that of the base 300d. The middle radical controller 330d may be provided with a material having a different surface recombination coefficient from that of the base 300d. If the middle region Md of the base 300d is omitted, the middle radical controller 330d may be omitted.

The edge radical controller 340d may be inserted and disposed in the base-side hole 301d positioned in the edge region Ed of the base 300d. A plurality of edge radical controllers 330d are provided corresponding to the base-side holes 301d positioned in the edge region Ed of the base 300d so that the edge radical controllers 340d may each be disposed in the base-side holes 301d positioned in the edge region Ed of the base 300d. The inner surface of the edge radical controller 340d may be the distribution hole 31d in the edge region of the shower head 30d.

The top of the edge radical controller 340d forms a coplanar surface with the upper surface of the base 300d, which may be a part of the upper surface of the shower head 30d. The bottom of the edge radical controller 340d forms a coplanar surface with the lower surface of the base 300d, which may be a part of the lower surface of the shower head 30d.

The edge radical controller 340d may be provided with a different surface recombination coefficient from that of the base 300d. The edge radical controller 340d may be provided with a material having a different surface recombination coefficient from that of the base 300d.

The center radical controller 320d, the middle radical controller 330d, and the edge radical controller 340d may be provided with different surface recombination coefficients. The center radical controller 320d, the middle radical controller 330d, and the edge radical controller 340d may be provided with materials having different surface recombination coefficients.

For example, the center radical controller 320d may be provided with a material having a higher surface recombination coefficient than the middle radical controller 330d and the edge radical controller 340d. The middle radical controller 330d may be provided with a material having a higher surface recombination coefficient than the edge radical controller 340d.

Accordingly, the surface recombination coefficient of the inner wall of the distribution holes 31d positioned in the center region of the shower head 30d may be greater than the surface recombination coefficient of the inner wall of the distribution holes 31d positioned in the middle region and edge region of the shower head 30d. The surface recombination coefficient of the inner wall of the distribution holes 31d positioned in the middle region of the shower head 30d may be greater than the surface recombination coefficient of the inner wall of the distribution holes 31d positioned in the edge region of the shower head 30d.

In one or more examples, since the top of the radical controller 310d forms the upper surface of the shower head 30d, the surface recombination coefficient of the upper surface of the center region of the shower head 30d may be greater than the surface recombination coefficients of the upper surfaces of the middle region and edge region of the shower head 30d. The surface recombination coefficient of the upper surface of the middle region of the shower head 30d may be greater than the surface recombination coefficient of the upper surface of the edge region of the shower head 30d.

In one or more examples, the center radical controller 320d may be provided with a material having a lower surface recombination coefficient than the middle radical controller 330d and the edge radical controller 340d. The middle radical controller 330d may be provided with a material having a lower surface recombination coefficient than the edge radical controller 340d.

Accordingly, the surface recombination coefficient of the inner wall of the distribution holes 31d positioned in the center region of the shower head 30d may be less than the surface recombination coefficient of the inner wall of the distribution holes 31d positioned in the middle region and edge region of the shower head 30d. The surface recombination coefficient of the inner wall of the distribution holes 31d positioned in the middle region of the shower head 30d may be less than the surface recombination coefficient of the inner wall of the distribution holes 31d positioned in the edge region of the shower head 30d.

In one or more examples, since the top of the radical controller 310d forms the upper surface of the shower head 30d, the surface recombination coefficient of the upper surface of the center region Cd of the shower head 30d may be less than the surface recombination coefficients of the upper surfaces of the middle region and edge region of the shower head 30d. The surface recombination coefficient of the upper surface of the middle region of the shower head 30d may be less than the surface recombination coefficient of the upper surface of the edge region of the shower head 30d.

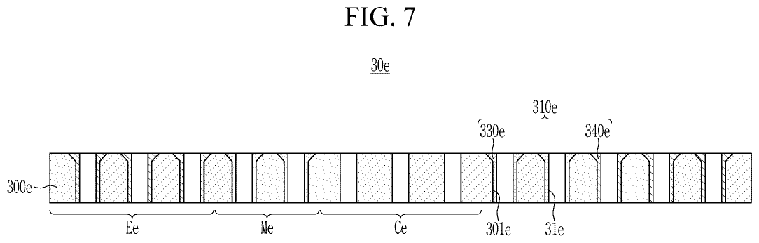

FIG. 7 illustrates a shower head 30e according to one or more embodiments.

Referring to FIG. 7, the shower head 30e according to one or more embodiments may include a base 300e and a radical controller 310e.

A plurality of base-side holes 301e may be positioned in the base 300e. The base 300e may include a center region Ce, a middle region Me, and an edge region Ee. The upper portion of the base-side hole 301e positioned in the middle region Me may have an area that increases as it goes upward. The upper portion of the base-side hole 301e positioned in the edge region Ee may have an area that increases as it goes upward. The base-side hole 301e positioned in the center region Ce may be a distribution hole 31e of the shower head 30e. Furthermore, similar to those described above in FIG. 6, the middle region Me may be omitted. The structure of the base 300e is the same as or similar to that of the base 300d of FIG. 6, so repeated description is omitted.

The radical controller 310e may be inserted and disposed in at least some of the plurality of base-side holes 301e. The radical controller 310e may be provided with a different surface recombination coefficient from that of the base 300e.

The radical controller 310e may include a middle radical controller 330e and an edge radical controller 340e.

The middle radical controller 330e may be inserted and disposed in the base-side hole 301e positioned in the middle region Me of the base 300e. The middle radical controller 330e may be provided with a different surface recombination coefficient from that of the base 300e. The middle radical controller 330e may be provided with a material having a different surface recombination coefficient from that of the base 300e. If the middle region Me of the base 300e is omitted, the middle radical controller 330e may be omitted.

The edge radical controller 340e may be inserted and disposed in the base-side hole 301e positioned in the edge region Ee of the base 300e. The edge radical controller 340e may be provided with a different surface recombination coefficient from that of the base 300e. The edge radical controller 340e may be provided with a material having a different surface recombination coefficient from that of the base 300e.

The edge radical controller 340e may be provided with a different surface recombination coefficient from that of the middle radical controller 330e. The edge radical controller 340e may be provided with a material having a different surface recombination coefficient from that of the middle radical controller 330e. The edge radical controller 340e may be provided with a material having a higher surface recombination coefficient than the middle radical controller 330e. In one or more examples, the edge radical controller 340e may be provided with a material having a lower surface recombination coefficient than the middle radical controller 330e.

The structures of the middle radical controller 330e and the edge radical controller 340e are the same as or similar to those described above in FIG. 6, so repeated description is omitted.

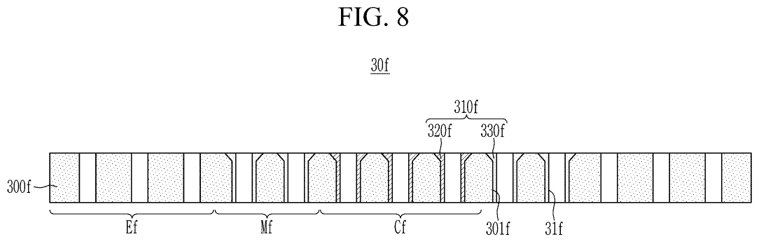

FIG. 8 illustrates a shower head 30f according to one or more embodiments.

Referring to FIG. 8, the shower head 30f according to one or more embodiments may include a base 300f and a radical controller 310f.

A plurality of base-side holes 301f may be positioned in the base 300f. The base 300f may include a center region Cf, a middle region Mf, and an edge region Ef. The upper portion of the base-side hole 301f positioned in the center region Cf may have an area that increases as it goes upward (e.g., vertical direction). In one or more examples, the upward direction (e.g., vertical direction), may be characterized as a direction that is perpendicular to a direction of the surface of the base. The upper portion of the base-side hole 301f positioned in the middle region Mf may have an area that increases as it goes upward. The base-side hole 301f positioned in the edge region Ef may be a distribution hole 31f of the shower head 30f. Furthermore, similar to those described above in FIG. 6, the middle region Mf may be omitted. The structure of the base 300f is the same as or similar to that of the base 300e of FIG. 6, so repeated description is omitted.

The radical controller 310f may be disposed to be inserted into at least some of the plurality of base-side holes 301f. The radical controller 310f may be provided with a different surface recombination coefficient from that of the base 300f.

The radical controller 310f may include a center radical controller 320f and a middle radical controller 330f.

The center radical controller 320f may be inserted and disposed in the base-side hole 301f positioned in the center region Cf of the base 300f. The center radical controller 320f may be provided with a different surface recombination coefficient from that of the base 300f. The center radical controller 320f may be provided with a material having a different surface recombination coefficient from that of the base 300f.

The middle radical controller 330f may be inserted and disposed in the base-side hole 301f positioned in the middle region Mf of the base 300f. The middle radical controller 330f may be provided with a different surface recombination coefficient from that of the base 300f. The middle radical controller 330f may be provided with a material having a different surface recombination coefficient from that of the base 300f.

The middle radical controller 330f may be provided with a surface recombination coefficient different from that of the center radical controller 320f. The middle radical controller 330f may be provided with a material having a different surface recombination coefficient from that of the center radical controller 320f. The middle radical controller 330f may be provided with a material having a higher surface recombination coefficient than the center radical controller 320f. In one or more examples, the middle radical controller 330f may be provided with a material having a lower surface recombination coefficient than the center radical controller 320f. If the middle region Mf of the base 300f is omitted, the middle radical controller 330f may be omitted.

Since the structures of the center radical controller 320f and the middle radical controller 330f are the same as or similar to those described above in FIG. 6, repeated description is omitted.

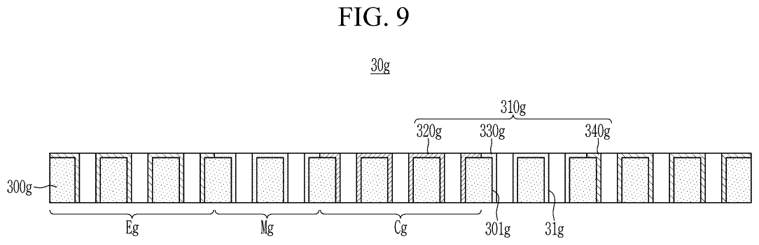

FIG. 9 illustrates a shower head 30g according to one or more embodiments.

Referring to FIG. 9, a shower head 30g according to one or more embodiments may include a base 300g and a radical controller 310g.

The shower head 30g may provide different surface recombination coefficients for each region on the inner walls of a plurality of distribution holes 31g. The upper surface of the shower head 30g may be provided with different surface recombination coefficients for each region.

The base 300g may provide a frame for the shower head 30g. The base 300g may be provided as a plate structure having a predetermined area. The lower surface of the base 300g may be the lower surface of the shower head 30g.

A plurality of base-side holes 301g may be positioned on the base 300g. For example, the plurality of base-side holes 301g may be positioned on a plurality of concentric circles. Depending on the region, the size of the base-side hole 301g may vary. The base 300g may be provided with a material such as silicone.

The base 300g may include a center region Cg, a middle region Mg, and an edge region Eg. The center region Cg may be positioned at the center of the base 300g and have a predetermined area. The center region Cg may be a circle having a predetermined length in a radial direction. The middle region Mg may be positioned on the outer circumference of the center region Cg and have a predetermined area. The middle region Mg may be ring-shaped and have a predetermined width in the radial direction. The edge region Eg may be positioned on the outer circumference of the middle region Mg and have a predetermined area. The edge region Eg may be ring-shaped and have a predetermined width in the radial direction. Below, a case where there is one middle region Mg between the center region Cg and the edge region Eg is described as an example. However, a plurality of middle regions Mg may be positioned between the center region Cg and the edge region Eg. In one or more examples, the middle region Mg may be omitted, and the center region Cg and the edge region Eg may be positioned to be in contact with each other.

The radical controller 310g may be disposed on the inner wall of the base-side hole 301g of the base 300g. Accordingly, the outer surface of the radical controller 310g positioned on the inner wall of the base-side hole 301g may be the distribution hole 31g of the shower head 30g. The radical controller 310g may be disposed on the upper surface of the base 300g. Accordingly, the outer surface of the radical controller 310g positioned on the upper surface of the base 300g may be the upper surface of the shower head 30g. The radical controller 310g may be a coating layer having a predetermined thickness.

The radical controller 310g may be provided with a different surface recombination coefficient from that of the base 300g. The radical controller 310g may be provided with a material having a different surface recombination coefficient from that of the base 300g. The radical controller 310g may provide different surface recombination coefficients for each region of the shower head 30g. The radical controller 310g may include a center radical controller 320g, a middle radical controller 330g, and an edge radical controller 340g.

The center radical controller 320g may be disposed on the inner wall of the base-side hole 301g of the center region Cg of the base 300g. The center radical controller 320g may be disposed on the upper surface of the center region Cg of the base 300g. The outer surface of the radical controller 310g positioned on the inner wall of the base-side hole 301g of the center region Cg may be the distribution hole 31g of the center region Cg of the shower head 30g. The outer surface of the radical controller 310g positioned on the upper surface of the center region Cg of the base 300g may be the upper surface of the center region Cg of the shower head 30g.

The center radical controller 320g may be provided with a different surface recombination coefficient from that of the base 300g. The center radical controller 320g may be provided with a material having a different surface recombination coefficient from that of the base 300g.

The middle radical controller 330g may be disposed on the inner wall of the base-side hole 301g of the middle region Mg of the base 300g. The middle radical controller 330g may be disposed on the upper surface of the middle region Mg of the base 300g. The outer surface of the radical controller 310g positioned on the inner wall of the base-side hole 301g of the middle region Mg may be the distribution hole 31g of the middle region of the shower head 30g. The outer surface of the radical controller 310g positioned on the upper surface of the middle region Mg of the base 300g may be the upper surface of the middle region of the shower head 30g.

The middle radical controller 330g may be provided with a different surface recombination coefficient from that of the base 300g. The middle radical controller 330g may be provided with a material having a different surface recombination coefficient from that of the base 300g.

If the middle region Mg of the base 300g is omitted, the middle radical controller 330g may be omitted.

The edge radical controller 340g may be disposed on the inner wall of the base-side hole 301g of the edge region Eg of the base 300g. The edge radical controller 340g may be disposed on the upper surface of the edge region Eg of the base 300g. The outer surface of the radical controller 310g positioned on the inner wall of the base-side hole 301g of the edge region Eg may be the distribution hole 31g of the edge region of the shower head 30g. The outer surface of the radical controller 310g positioned on the upper surface of the edge region Eg of the base 300g may be the upper surface of the edge region of the shower head 30g.

The edge radical controller 340g may be provided with a different surface recombination coefficient from that of the base 300g. The edge radical controller 340g may be provided with a material having a different surface recombination coefficient from that of the base 300g.

The center radical controller 320g, the middle radical controller 330g, and the edge radical controller 340g may be provided with different surface recombination coefficients. The center radical controller 320g, the middle radical controller 330g, and the edge radical controller 340g may be provided with materials having different surface recombination coefficients.

For example, the center radical controller 320g may be provided with a material having a higher surface recombination coefficient than the middle radical controller 330g and the edge radical controller 340g. The middle radical controller 330g may be provided with a material having a higher surface recombination coefficient than the edge radical controller 340g.

Accordingly, the surface recombination coefficient of the inner wall of the distribution holes 31g positioned in the center region Cg of the shower head 30g may be greater than the surface recombination coefficient of the inner wall of the distribution holes 31g positioned in the middle region and edge region Eg of the shower head 30g. The surface recombination coefficient of the inner wall of the distribution holes 31g positioned in the middle region of the shower head 30g may be greater than the surface recombination coefficient of the inner wall of the distribution holes 31g positioned in the edge region of the shower head 30g.

In one or more examples, the surface recombination coefficient of the upper surface of the center region Cg of the shower head 30g may be greater than the surface recombination coefficients of the upper surfaces of the middle region and the edge region Eg of the shower head 30g. The surface recombination coefficient of the upper surface of the middle region of the shower head 30g may be greater than the surface recombination coefficient of the upper surface of the edge region of the shower head 30g.

In one or more examples, the center radical controller 320g may be provided with a material having a lower surface recombination coefficient than the middle radical controller 330g and the edge radical controller 340g. The middle radical controller 330g may be provided with a material having a lower surface recombination coefficient than the edge radical controller 340g.

Accordingly, the surface recombination coefficient of the inner wall of the distribution holes 31g positioned in the center region Cg of the shower head 30g may be less than the surface recombination coefficient of the inner wall of the distribution holes 31g positioned in the middle region and edge region Eg of the shower head 30g. The surface recombination coefficient of the inner wall of the distribution holes 31g positioned in the middle region of the shower head 30g may be less than the surface recombination coefficient of the inner wall of the distribution holes 31g positioned in the edge region of the shower head 30g.

In one or more examples, the surface recombination coefficient of the upper surface of the center region Cg of the shower head 30g may be less than the surface recombination coefficients of the upper surfaces of the middle region and the edge region Eg of the shower head 30g. The surface recombination coefficient of the upper surface of the middle region of the shower head 30g may be less than the surface recombination coefficient of the upper surface of the edge region of the shower head 30g.

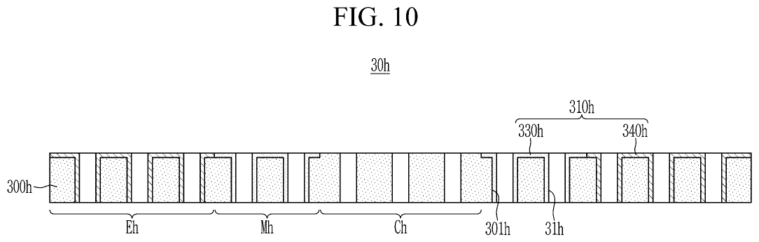

FIG. 10 illustrates a shower head 30h according to one or more embodiments.

Referring to FIG. 10, the shower head 30h according to one or more embodiments may include a base 300h and a radical controller 310h.

A plurality of base-side holes 301h may be positioned in the base 300h. The base 300h may include a center region Ch, a middle region Mh, and an edge region Eh. The base-side hole 301h positioned in the center region Ch may be a distribution hole 31h of the shower head 30h. Furthermore, similar to those described above in FIG. 9, the middle region Mh may be omitted. The structure of the base 300h is the same as or similar to that of the base 300g of FIG. 9, so repeated description is omitted.

The radical controller 310h may be disposed on the inner wall of at least some of the plurality of base-side holes 301h. Accordingly, the outer surface of the radical controller 310h positioned on the inner wall of the base-side hole 301h may be the distribution hole 31h of the shower head 30h. The radical controller 310h may be disposed on at least a portion of the upper surface of the base 300h. Accordingly, the outer surface of the radical controller 310h positioned on the upper surface of the base 300h may be the upper surface of the shower head 30h. The radical controller 310h may be a coating layer having a predetermined thickness. As illustrated in FIG. 10, the radical controller 310h is not included in the center region Ch.

The radical controller 310h may be provided with a different surface recombination coefficient from that of the base 300h. The radical controller 310h may be provided with a material having a different surface recombination coefficient from that of the base 300h. The radical controller 310h may include a middle radical controller 330h and an edge radical controller 340h.

The middle radical controller 330h may be disposed on the inner wall of the base-side hole 301h of the middle region Mh of the base 300h. The middle radical controller 330h may be disposed on the upper surface of the middle region Mh of the base 300h. The outer surface of the radical controller 310h positioned on the inner wall of the base-side hole 301h of the middle region Mh may be the distribution hole 31h of the middle region of the shower head 30h. The outer surface of the radical controller 310h positioned on the upper surface of the middle region Mh of the base 300h may be the upper surface of the middle region of the shower head 30h.

The middle radical controller 330h may be provided with a different surface recombination coefficient from that of the base 300h. The middle radical controller 330h may be provided with a material having a different surface recombination coefficient from that of the base 300h.

If the middle region Mh of the base 300h is omitted, the middle radical controller 330h may be omitted.

The edge radical controller 340h may be disposed on the inner wall of the base-side hole 301h of the edge region Eh of the base 300h. The edge radical controller 340h may be disposed on the upper surface of the edge region Eh of the base 300h. The outer surface of the radical controller 310h positioned on the inner wall of the base-side hole 301h of the edge region Eh may be the distribution hole 31h of the edge region of the shower head 30h. The outer surface of the radical controller 310h positioned on the upper surface of the edge region Eh of the base 300h may be the upper surface of the edge region of the shower head 30h.

The edge radical controller 340h may be provided with a different surface recombination coefficient from that of the base 300h. The edge radical controller 340h may be provided with a material having a different surface recombination coefficient from that of the base 300h.

The edge radical controller 340h may be provided with a material having a higher surface recombination coefficient than the middle radical controller 330h. In one or more examples, the edge radical controller 340h may be provided with a material having a lower surface recombination coefficient than the middle radical controller 330h.

Since the structures of the middle radical controller 330h and the edge radical controller 340h are the same as or similar to those described above in FIG. 9, repeated description is omitted.

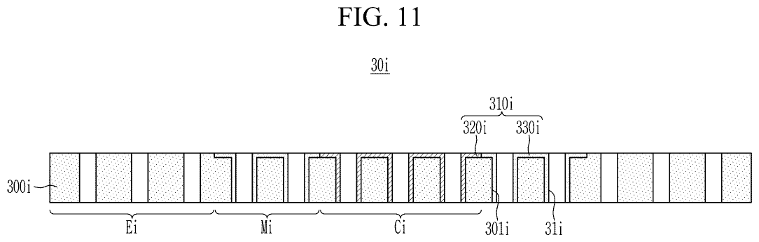

FIG. 11 illustrates a shower head 30i according to one or more embodiments.

Referring to FIG. 11, the shower head 30i according to one or more embodiments may include a base 300i and a radical controller 310i.

A plurality of base-side holes 301i may be positioned in the base 300i. The base 300i may include a center region Ci, a middle region Mi, and an edge region Ei. The base-side hole 301i positioned in the edge region Ei may be a distribution hole 31i of the shower head 30i.

Furthermore, similar to the above description in FIG. 9, the middle region Mi may be omitted. Since the structure of the base 300i is the same as or similar to that of the base 300g of FIG. 9, repeated description is omitted.

The radical controller 310i may be disposed on the inner wall of at least some of the plurality of base-side holes 301i. Accordingly, the outer surface of the radical controller 310i positioned on the inner wall of the base-side hole 301i may be the distribution hole 31i of the shower head 30i. The radical controller 310i may be disposed on at least a portion of the upper surface of the base 300i. Accordingly, the outer surface of the radical controller 310i positioned on the upper surface of the base 300i may be the upper surface of the shower head 30i. The radical controller 310i may be a coating layer having a predetermined thickness. As illustrated in FIG. 11, the radical controller 310i may not be included in the edge region Ei.

The radical controller 310i may be provided with a different surface recombination coefficient from that of the base 300i. The radical controller 310i may be provided with a material having a different surface recombination coefficient from that of the base 300i. The radical controller 310i may include a center radical controller 320i and a middle radical controller 330i.

The center radical controller 320i may be disposed on the inner wall of the base-side hole 301i of the center region Ci of the base 300i. The center radical controller 320i may be disposed on the upper surface of the center region Ci of the base 300i. The outer surface of the radical controller 310i positioned on the inner wall of the base-side hole 301i of the center region Ci may be the distribution hole 31i of the center region Ci of the shower head 30i. The outer surface of the radical controller 310i positioned on the upper surface of the center region Ci of the base 300i may be the upper surface of the center region Ci of the shower head 30i.

The center radical controller 320i may be provided with a different surface recombination coefficient from that of the base 300i. The center radical controller 320i may be provided with a material having a different surface recombination coefficient from that of the base 300i.

The middle radical controller 330i may be disposed on the inner wall of the base-side hole 301i of the middle region Mi of the base 300i. The middle radical controller 330i may be disposed on the upper surface of the middle region Mi of the base 300i. The outer surface of the radical controller 310i positioned on the inner wall of the base-side hole 301i of the middle region Mi may be the distribution hole 31i of the middle region of the shower head 30i. The outer surface of the radical controller 310i positioned on the upper surface of the middle region Mi of the base 300i may be the upper surface of the middle region of the shower head 30i.

The middle radical controller 330i may be provided with a different surface recombination coefficient from that of the base 300i. The middle radical controller 330i may be provided with a material having a different surface recombination coefficient from that of the base 300i.

The middle radical controller 330i may be provided with a material having a higher surface recombination coefficient than the center radical controller 320i. In one or more examples, the middle radical controller 330i may be provided with a material having a lower surface recombination coefficient than the center radical controller 320i. If the middle region Mi of the base 300i is omitted, the middle radical controller 330i may be omitted.

Since the structures of the center radical controller 320i and the middle radical controller 330i are the same as or similar to those described above in FIG. 9, repeated description is omitted.

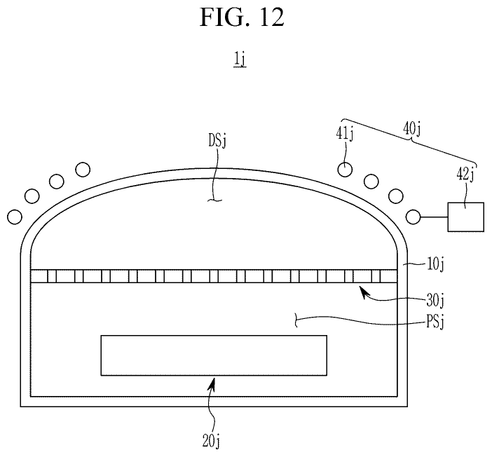

FIG. 12 illustrates a substrate processing apparatus 1j according to one or more embodiments.

Referring to FIG. 12, the substrate processing apparatus 1j according to one or more embodiments may include a chamber 10j, a supporting member 20j, a shower head 30j, and a plasma source 40j.

The plasma source 40j may allow plasma to be supplied to the interior of the chamber 10j. The plasma source 40j may allow plasma to be supplied to the gas distribution space DSj. The plasma source 40j may allow gas to be excited to a plasma state inside the chamber 10j. The plasma source 40j may allow gas to be excited to a plasma state in the gas distribution space DSj. The plasma source 40j may include a plasma excitation member 41j and a source power supplier 42j.

The plasma excitation member 41j allows energy for plasma excitation to be applied inside the chamber 10j. The plasma excitation member 41j may allow energy for plasma excitation to be applied to the gas distribution space DSj. The plasma excitation member 41j may have an antenna structure. For example, the plasma excitation member 41j may be ring-shaped, arc-shaped, or the like. In addition, the plasma excitation member 41j may have a spirally wound structure and may be disposed on the same plane or on at least two planes of different heights.

The plasma excitation member 41j is disposed outside the chamber 10j. The plasma excitation member 41j may be disposed adjacent to the upper surface of the upper wall of the chamber 10j. For example, the upper wall of the chamber 10j is dome-shaped, and the plasma excitation member 41j may be disposed to face the internal space of the chamber 10j with the upper wall of the chamber 10j therebetween.

The source power supplier 42j provides power for plasma excitation. The source power supplier 42j may be electrically connected to the plasma excitation member 41j. The source power supplier 42j may include a high-frequency power source that generates high-frequency power. The source power supplier 42j may include an RF power source. The plasma excitation member 41j generates electromagnetic waves through power provided by the source power supplier 42j. The gas supplied into the interior of the chamber 10j may be excited into plasma by electromagnetic waves generated by the plasma excitation member 41j.

The interior of the chamber 10j may be partitioned by the shower head 30j into a process space PSj and a gas distribution space DSj.

Since the structures of the chamber 10j and the supporting member 20j are the same as or similar to those in FIG. 1, repeated description is omitted.

Since the structure of the shower head 30j is the same as or similar to what is described above in FIGS. 1 to 11, repeated description is omitted.

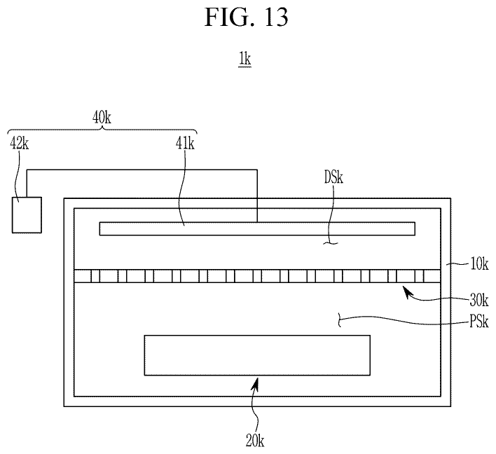

FIG. 13 illustrates a substrate processing apparatus 1k according to one or more embodiments.

Referring to FIG. 13, the substrate processing apparatus 1k according to one or more embodiments may include a chamber 10k, a supporting member 20k, a shower head 30k, and a plasma source 40k.

The plasma source 40k may allow plasma to be supplied to the interior of the chamber 10k. The plasma source 40k may allow plasma to be supplied to the gas distribution space DSk. The plasma source 40k may allow gas to be excited into a plasma state inside the chamber 10k. The plasma source 40k may allow gas to be excited into a plasma state in the gas distribution space DSk. The plasma source 40k may include a plasma excitation member 41k and a source power supplier 42k.

The plasma excitation member 41k allows energy for plasma excitation to be applied to the gas distribution space DSk. The lower surface of the plasma excitation member 41k may be positioned to face the interior of the chamber 10k. For example, the plasma excitation member 41k may be manufactured separately from the chamber 10k and connected to the chamber 10k. In one or more examples, the plasma excitation member 41k may be provided integrally with the upper structure of the chamber 10k. For example, the upper structure of the chamber 10k may function as the plasma excitation member 41k.

The plasma excitation member 41k may be disposed at the upper portion of the gas distribution space DSk. The plasma excitation member 41k may be provided with a predetermined area made of a conductive material.

The source power supplier 42k provides power for plasma excitation. The source power supplier 42k may be electrically connected to the plasma excitation member 41k. The source power supplier 42k may include a high-frequency power source that generates high-frequency power. The source power supplier 42k may include an RF power source.

Gas flowed into the chamber 10k may be excited into plasma by an electric field formed inside the chamber 10k. Specifically, the gas may be excited into a plasma by a capacitively coupled plasma (CCP) source. The capacitively coupled plasma source may include an upper electrode and a lower electrode. The upper electrode and the lower electrode may be disposed in the vertical direction facing each other inside the chamber 10k. By applying high-frequency power to at least one of the upper electrode and the lower electrode, an electromagnetic field may be formed in the space between the upper electrode and the lower electrode, and the gas supplied to this space may be excited into a plasma state. The upper electrode may be the plasma excitation member 41k, and the lower electrode may be the shower head 30k. In one or more examples, the upper electrode may be the plasma excitation member 41k, and the lower electrode may be additionally disposed between the plasma excitation member 41k and the shower head 30k. The high-frequency power source may be connected to only one of the upper and lower electrodes. For example, the lower electrode may be grounded, and only the upper electrode may be connected to the high-frequency power source.

The interior of the chamber 10k may be partitioned by the shower head 30k into a process space PSk and a distribution space.

Since the structures of the chamber 10k and the supporting member 20k are the same as or similar to those described in FIG. 1, repeated description is omitted.

Since the structure of the shower head 30k is the same as or similar to that described above in FIGS. 1 to 11, repeated description is omitted.

While this disclosure has been described in connection with what is presently considered to be practical embodiments, it should be understood that the disclosure is not limited to the disclosed embodiments, but, on the contrary, is intended to cover various modifications and equivalent arrangements included within the spirit and scope of the appended claims.

### DESCRIPTION OF SYMBOLS

10: Chamber
20: Supporting member
30: Shower head
40: Plasma source
300: Base
310: Radical controller
320: Center radical controller
330: Middle radical controller
340: Edge radical controller

What is claimed is:

1. A substrate processing apparatus, comprising:
a chamber;
a supporting member inside the chamber to support a substrate; and
a shower head connected to the chamber,
wherein the shower head comprises a plurality of regions, and
wherein at least two regions of the plurality of regions of the shower head have different surface recombination coefficients for radicals.

2. The substrate processing apparatus of claim 1, wherein the shower head further comprises:
a base, and
a radical controller on the base,
wherein the radical controller has different surface recombination coefficients for radicals from that of the base.

3. The substrate processing apparatus of claim 2, wherein
the radical controller has a plate structure and is detachably from the base.

4. The substrate processing apparatus of claim 2, wherein the radical controller further comprises:
a first radical controller, and
a second radical controller, and
wherein the first radical controller is closer to a center region of the base than the second radical controller.

5. The substrate processing apparatus of claim 4, wherein
the first radical controller comprises a first material,
the second radical controller comprises a second material, and
the first material has a higher surface recombination coefficient for radicals than the second material.

6. The substrate processing apparatus of claim 4, wherein
the first radical controller comprises a first material,
the second radical controller comprises a second material, and
the first material has a a lower surface recombination coefficient for radicals than the second material.

7. The substrate processing apparatus of claim 2, wherein the base has a plate structure and has a plurality of base-side holes,
wherein the radical controller has a pipe structure,
wherein the radical controller is inserted into one or more of the plurality of base-side holes, and
wherein the radical controller has different surface recombination coefficients for radicals from that of the base.

8. The substrate processing apparatus of claim 7, wherein the radical controller further comprises:
a first radical controller inserted into a first region of the base, and
a second radical controller inserted into a second region of the base,
wherein the first region of the base is closer to a center of the base than the second region.

9. The substrate processing apparatus of claim 7, wherein
the plurality of base-side holes has an area that increases in a direction perpendicular to a direction of a surface of the base, and
an outer surface of the radical controller corresponds to a shape of the plurality of base-side holes.

10. The substrate processing apparatus of claim 2, wherein the base has a plate structure and has a plurality of base-side holes,
wherein the radical controller is on an inner wall of at least one or more of the plurality of base-side holes, and
wherein the radical controller has different surface recombination coefficients for radicals from that of the base.

11. The substrate processing apparatus of claim 2, wherein the base has a plate structure and has a plurality of base-side holes,
wherein the radical controller is on at least a portion of a surface of the base, and
wherein the radical controller has different surface recombination coefficients for radicals from that of the base.

12. A substrate processing apparatus, comprising:
a chamber;
a supporting member inside the chamber to support a substrate;
a plasma source configured to supply plasma into the interior of the chamber; and
a shower head connected to the chamber and having a plurality of distribution holes,
wherein the shower head comprises a plurality of regions, and
wherein each region of the plurality of regions has different surface recombination coefficients for radicals on inner walls of the plurality of distribution holes.

13. The substrate processing apparatus of claim 12, wherein the shower head comprises:
a base having a plate structure and having a plurality of base-side holes; and
a radical controller having a plurality of controller-side holes on at least a portion of the base, and
wherein the radical controller has a material having different surface recombination coefficients for radicals from that of the base.

14. The substrate processing apparatus of claim 13, wherein the radical controller comprises:
a first radical controller, and
an second radical controller,
wherein the first radical controller is closer to a center region of the base than the second radical controller.

15. The substrate processing apparatus of claim 12, wherein the shower head comprises:
a base having a plate structure and having a plurality of base-side holes positioned therein; and
a radical controller having a pipe structure,
wherein the radical controller is inserted into one or more of the plurality of base-side holes, and
wherein the radical controller has a material having different surface recombination coefficients for radicals from that of the base.

16. The substrate processing apparatus of claim 12, wherein the shower head comprises:
the base having a plate structure and having a plurality of base-side holes; and
a radical controller on an inner wall of one or more of the plurality of base-side holes, and
wherein the radical controller has a material having different surface recombination coefficients for radicals from that of the base.

17. The substrate processing apparatus of claim 12, wherein the shower head comprises:
a base having a plate structure and having a plurality of base-side holes; and
a radical controller on at least a portion of a surface of the base, and
wherein the radical controller has a material having different surface recombination coefficients for radicals from that of the base.

18. A substrate processing apparatus, comprising:
a chamber;
a supporting member inside the chamber to support a substrate;
a shower head dividing an interior of the chamber into a process space and a gas distribution space, the shower head having a plurality of distribution holes; and
a plasma source configured to supply plasma to the gas distribution space,
wherein the shower head has a plurality of regions, and
wherein each region of the plurality of regions of the shower head have different surface recombination coefficients for radicals on inner walls of the plurality of distribution holes.

19. The substrate processing apparatus of claim 18, wherein the shower head comprises:
a base, and
a radical controller on the base and having a plate structure of a material having different surface recombination coefficients for radicals from that of the base.

20. The substrate processing apparatus of claim 19, wherein:
the base has a plate structure and has a plurality of base-side holes,
the radical controller has a pipe structure,
the radical controller is inserted into at least one or more of the plurality of base-side holes, and
the radical controller had a material having different surface recombination coefficients for radicals from that of the base.
